(19) United States
(12) Patent Application Publication
(10) Pub. No.: US 2011/0244128 A1
(43) Pub. Date: Oct. 6, 2011

(54) FLOW PLATE UTILIZATION IN FILAMENT ASSISTED CHEMICAL VAPOR DEPOSITION

(75) Inventors: Jozef Brcka, Loundonville, NY (US); Jacques Faguet, Albany, NY (US)

(73) Assignee: TOKYO ELECTRON LIMITED, Tokyo (JP)

(21) Appl. No.: 12/751,784

(22) Filed: Mar. 31, 2010

(51) Int. Cl. C23C 16/44; C23C 16/00; B23P 15/00; G06G 7/50

(52) U.S. Cl. 427/248.1; 118/724; 29/592; 703/9

(57) ABSTRACT

A filament assisted chemical vapor deposition (FACVD) system. The FACVD system includes a gas distribution assembly, heater filament assembly, and a flow plate that is disposed between the gas distribution assembly and the heater filament assembly. The heater filament assembly and the flow plate have a corresponding extent across a dimension of the reactor and are separated by different distances across that extent.

### TECHNICAL FIELD

The present invention relates generally to hardware systems and methods of using those hardware systems for the deposition of a film onto a substrate and, more particularly, to hardware systems and processing methods for filament assisted chemical vapor deposition of a film.

### BACKGROUND

Vapor deposition is a common technique used in forming thin films during the production of an integrated circuit (IC) in semiconductor device manufacturing. Vapor deposition is also useful in forming conformal thin films over and on features within a substrate.

Chemical vapor deposition (CVD) processes generally include the introduction of a continuous stream of film precursor vapor into a reactor containing the substrate on a substrate support, which is generally heated to an elevated temperature. The film precursor vapor comprises the principle atomic or molecular species that will ultimately form the thin film on the substrate. Film formation typically occurs when precursor vapor that is chemisorbed onto the heated surface of the substrate thermally decomposes and reacts. Additional gaseous components may be used to assist in the decomposing or reacting of the chemisorbed precursor vapor.

In plasma enhanced CVD (PECVD), a plasma is generated within the reactor and utilized to alter or enhance the film deposition mechanism. For example, plasma excitation may allow a particular film-forming reaction to proceed at substrate temperatures that are significantly lower than conventional CVD temperatures. While PECVD may be used to deposit a wide variety of films at this lower substrate temperature, the use of the plasma may result in high energy ion bombardment or vacuum ultraviolet (VUV) radiation of the substrate during film growth, either of which may result in dangling bonds, trapped free radicals within the deposited film, or damage to the substrate.

In filament assisted CVD (FACVD), the film precursor is decomposed by a resistively heated filament positioned within the process space. The resultant fragmented molecules adsorb and react on the surface of the substrate. Unlike PECVD, plasma formation is not necessary for the deposition process, making FACVD particularly advantageous in reducing damage to the substrate during the deposition process.

Yet, there remain areas in need of improvement within FACVD, particularly with regulating the uniformity of film deposition.

### SUMMARY

In one illustrative embodiment, the present invention is directed to a filament assisted chemical vapor deposition (FACVD) processing system. The FACVD processing system includes a reactor that encloses a processing space. There is a substrate support on a first side of the processing space and a gas distribution assembly on a second side of the processing space, opposite to the first side. The gas distribution assembly is operable to supply at least one reactive gas to the processing space. A heater filament assembly is positioned between the gas distribution assembly and the substrate support and is operable to thermally decompose the at least one reactive gas when the at least one reactive gas is flowing through. A flow plate is disposed between the gas distribution assembly and the heater filament assembly and is configured to direct the flow of the at least one reactive gas onto the heater filament assembly. The flow plate and the heater filament assembly have a corresponding extent across a dimension of the reactor and are separated by different distances across that extent.

In another illustrative embodiment, the present invention is directed to a filament assisted chemical vapor deposition (FACVD) processing system. The FACVD processing system includes a reactor that encloses a processing space. Within the reactor there is a substrate support on a first side and a gas distribution assembly on a second side that is opposite the first side. The gas distribution assembly supplies at least one reactive gas to the processing space. A heater filament assembly is positioned between the gas distribution assembly and the substrate support and is operable to thermally decompose the at least one reactive gas as the at least one reactive gas flows through the heater filament assembly. A non-planar flow plate is disposed between the gas distribution assembly and the heater filament assembly for directing a flow of the at least one reactive gas onto the heater filament assembly. The non-planar flow plate and the heater filament assembly are centered at a common axis and are separated by a first distance at a first point and by a second distance at a second point. The first and second points are defined by first and second line segments extending from the common axis between the non-planar flow plate and the heater filament assembly.

Another illustrative embodiment of the present invention includes a method of designing a flow plate to achieve a uniform film formation profile on the substrate. The method includes detecting a present film deposition profile on the substrate. The present film deposition profile is compared to a desired film deposition profile such that a desired heat distribution profile for the heater filament assembly may be determined. The FACVD processing system is modeled to determine a flow plate profile to achieve the desired film deposition profile.

In another illustrative embodiment, a method of operating an FACVD processing system is described. At least one reactive material is deposited as the thin film on the substrate. A present film deposition profile is detected for the thin film. A corrected flow plate profile is determined by modeling the FACVD processing system. A corrected flow plate constructed in accordance with the corrected flow plate profile is installed into the FACVD system. Deposition of the thin film then continues.

Another illustrative embodiment is directed to an FACVD processing method for depositing a film on a substrate. The method includes placing a substrate on the substrate support. At least one reactive gas is introduced into the reactor through a gas distribution assembly. The introduced at least one reactive gas flows through a heater assembly and is thermally decomposed by heat provided by the heater filament assembly. The flow of the at least one reactive gas toward the heater filament assembly is directed through a flow plate that is shaped in relation to the heater filament assembly to provide differing distances at a first position on the flow plate as compared to a second position on the flow plate.

### BRIEF DESCRIPTION OF THE DRAWINGS

FIG. 1 is a diagrammatic view of one exemplary embodiment of a reactor for an FACVD system.

FIG. 2 is a diagrammatic view of one exemplary embodiment of a heater filament assembly for the reactor of the FACVD system.

FIG. 3 is a flow chart illustrating successive steps of one exemplary method of operating the reactor of FIG. 1.

FIG. 4 is a schematic representation of the heat transfer mechanisms associated with the heater filament assembly of FIG. 2.

FIGS. 5A-5C are diagrammatic views of various exemplary flow plate profiles in accordance with embodiments of the present invention.

FIG. 5D is a diagrammatic view of an exemplary heater filament assembly profile in accordance with embodiments of the present invention.

FIG. 6 is a schematic representation of an exemplary embodiment of a hardware and software environment for a computing system for modeling the FACVD system.

FIGS. 7-7A are flow charts illustrating successive steps of one exemplary method of operating and modeling the FACVD system.

FIG. 8A includes exemplary temperature profile data of the heater filament assembly resulting from the modeling of the FACVD processing system when operated with a planar flow plate, a conical flow plate, and a stepwise flow plate.

FIG. 8B is a graphical representation of the exemplary temperature profile data illustrated in FIG. 8A.

FIG. 9A includes exemplary data of the relative concentrations of ethylene glycol di-acrylate (EGDA) precursor near the heater filament assembly resulting from the modeling of the FACVD processing system when operated with a planar flow plate, a conical flow plate, and a stepwise flow plate.

FIG. 9B includes exemplary data of the relative concentrations of non-decomposed tert-butyl peroxide (TBPO_{ND}) initiator near the heater filament assembly resulting from the modeling of the FACVD processing system when operated with a planar flow plate, a conical flow plate, and a stepwise flow plate.

FIG. 9C includes exemplary data of the relative concentrations of the radicals from the decomposition of the TBPO initiator near the heater filament assembly resulting from the modeling of the FACVD processing system when operated with a planar flow plate, a conical flow plate, and a stepwise flow plate.

### DETAILED DESCRIPTION

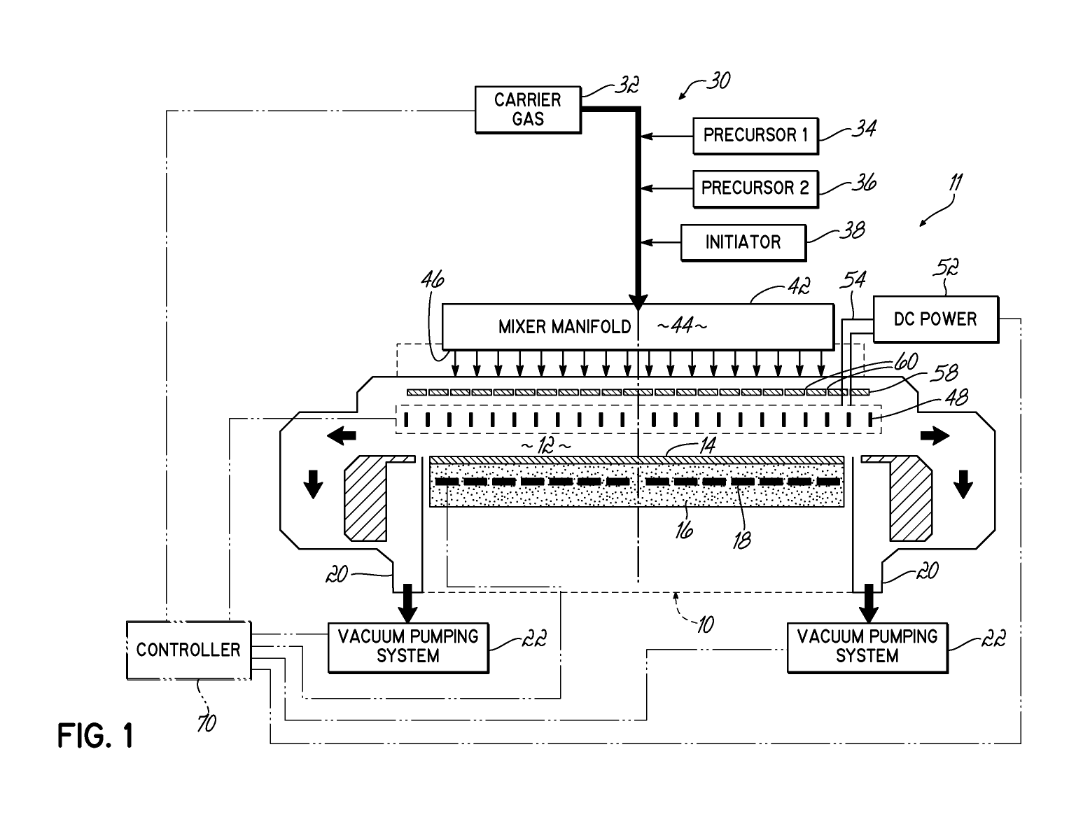

FIG. 1 illustrates one embodiment of a filament assisted chemical vapor deposition (FACVD) reactor 10 of an FACVD system 11 enclosing a processing space 12 for depositing a thin film onto a substrate 14 positioned on a substrate support 16. The substrate support 16 is situated in the reactor 10 on one side of the processing space 12 and supports the substrate 14 on an upper surface facing the processing space 12.

The substrate 14 may, for example, be a silicon (Si) substrate, such as an n- or p-type substrate, depending on the type of device to be formed. The substrate 14 may be of any size, for example, 200 mm or 300 mm in diameter or larger. While only one substrate 14 is specifically illustrated, it would be understood that more than one substrate 14 may be processed simultaneously, such as during batch processing. Other substrates and configurations may also be used. For example, rectangular substrates such as large glass substrates or liquid crystal displays (LCDs), may be processed in either a horizontal or vertical arrangement within the processing space 12. In yet another arrangement, a flexible substrate may be processed by running roller-to-roller in a known manner where the substrate holder may be configured as a roller.

The substrate support 16 may include one or more temperature control elements 18 operable to control the temperature of the substrate 14 during operation of the reactor 10. The one or more temperature control elements 18 may include a substrate heating system, a substrate cooling system, or both. In one embodiment, the substrate heating and cooling systems may include a recirculating fluid flow for exchanging heat between the substrate support 16 and a heat exchanger system (not shown). In yet other embodiments, the heating and cooling systems may include resistive heating elements or thermo-electric heaters or coolers. The substrate heating and cooling system may be arranged to include one or more thermal zones, for example, an inner zone and an outer zone, whereby the temperature of the one or more thermal zones may be independently controlled during the operation of the reactor 10.

The substrate support 16 may further include an electrical or mechanical substrate clamping system (not shown) to clamp the substrate 14 to the upper surface of the substrate support 16. One exemplary embodiment of a suitable clamping system may include an electrostatic chuck (ESC).

Additionally, the substrate support 16 may include a backside gas supply system (not shown) to facilitate the delivery of a heat transfer gas (for example, helium; He) to the back side of the substrate 14 to improve the gas-gap thermal conductance between the substrate 14 and the upper surface of the substrate support 16. The backside gas supply system may be utilized when additional control of an elevated or reduced temperature of the substrate 14 is required. The backside gas supply system may be separated into one or more delivery zones, whereby the pressure of the heat transfer gas may be independently varied between the one or more delivery zones.

The reactor 10 may further be coupled via a duct 20 to a vacuum pumping system 22 that is operable to evacuate the reactor 10 to an internal pressure during operation of the reactor 10. One exemplary vacuum pumping system 22 may include a turbo-molecular vacuum pump (TMP) capable of pumping speeds of up to about 5000 Liters per second (Ls⁻¹) and having a gate valve (not shown) that is operable to throttle the internal pressure as necessary. TMPs may be used for low pressure processes, i.e., those operating at less than about 1 Torr. High pressure processes, i.e., those operating at greater than 1 Torr, may be accomplished with a mechanical booster pump or a dry roughing pump. Monitoring of the internal pressure may be accomplished with a pressure measuring device (not shown), for example, a Type 628B Baratron absolute capacitance manometer that is commercially available from MKS Instruments, Inc. (Andover, Mass.).

A gas delivery system 30 may be coupled to an end of the reactor 10 that opposes the substrate support 16 and is operable to introduce one or more gases into the processing space 12 in the reactor 10. The one or more gases may include one or more reactive gases and, optionally, non-reactive gas(es), such as film forming materials for forming a thin film on the substrate 14 and/or inert gases for use as a carrier gas, dilution gas, or purging gas. Appropriate thin films may include a conductive film, a non-conductive film, semi-conductive films having various electrical properties, a dielectric film such as a low dielectric constant (low-k) film or an ultra-low-k film, or for application as sacrificial layers in forming air gap dielectrics. Accordingly, the gas delivery system 30 includes a plurality of conduits coupling the reactor 10 to one or more gas sources, each containing a different reactive film forming material or inert gas, such as a carrier gas 32, one or more precursors (first and second precursors 34, 36 are shown), initiators 38, or other gases as would be known to those of ordinary skill in the art. Precursors 34, 36 may include one or more chemical species, typically monomers, that are decomposed (to radicals or fragments), adsorbed onto the surface of the substrate 14, and reacted to form the film in a manner described in greater detail below. The initiator 38 may be included to assist with the film forming process, for example, by undergoing thermal decomposition and reacting with one of the two precursors 34, 36. Alternatively, the initiator 38 may perform as a catalyst, thermally decomposing the precursors 34, 36. In other embodiments, a porogen (not shown) may be included that is operable to create pores within the deposited film. In still other embodiments, a cross-linker (not shown) may be desired and included with the film forming materials. Exemplary chemistries may include those described in U.S. patent application Ser. Nos. 11/693,067; 12/044,574; and 12/511,832, the disclosures of which are incorporated herein by reference, in their entireties.

The carrier gas 32 may be used when one or more of the precursors 34, 36 includes a material that transforms from a non-gaseous state to a gaseous state, such as by sublimation or evaporation. The carrier gas 32 assists with transporting the material in the gaseous state from the system in which it is transformed through the conduit(s) of the gas delivery system 30 to the reactor 10. Purge gases or dilution gases may also be used as necessary. Suitable carrier, purge, or dilution gases may include the noble gases, i.e., helium (He), neon (Ne), argon (Ar), krypton (Kr), xenon (Xe), or radon (Rn), or combinations thereof.

The gas delivery system 30 terminates at a mixer manifold 42, which provides a plenum 44 in which the film forming materials combine. The opposing end of the mixer manifold 42 includes a gas distribution plate 46 with a plurality of orifices (not shown) having shapes, numbers, and distributions selected for achieving a particular distribution of the one or more gases into the processing space 12. The mixer manifold 42 may be a showerhead assembly or other similar device that is known to one of ordinary skill in the art.

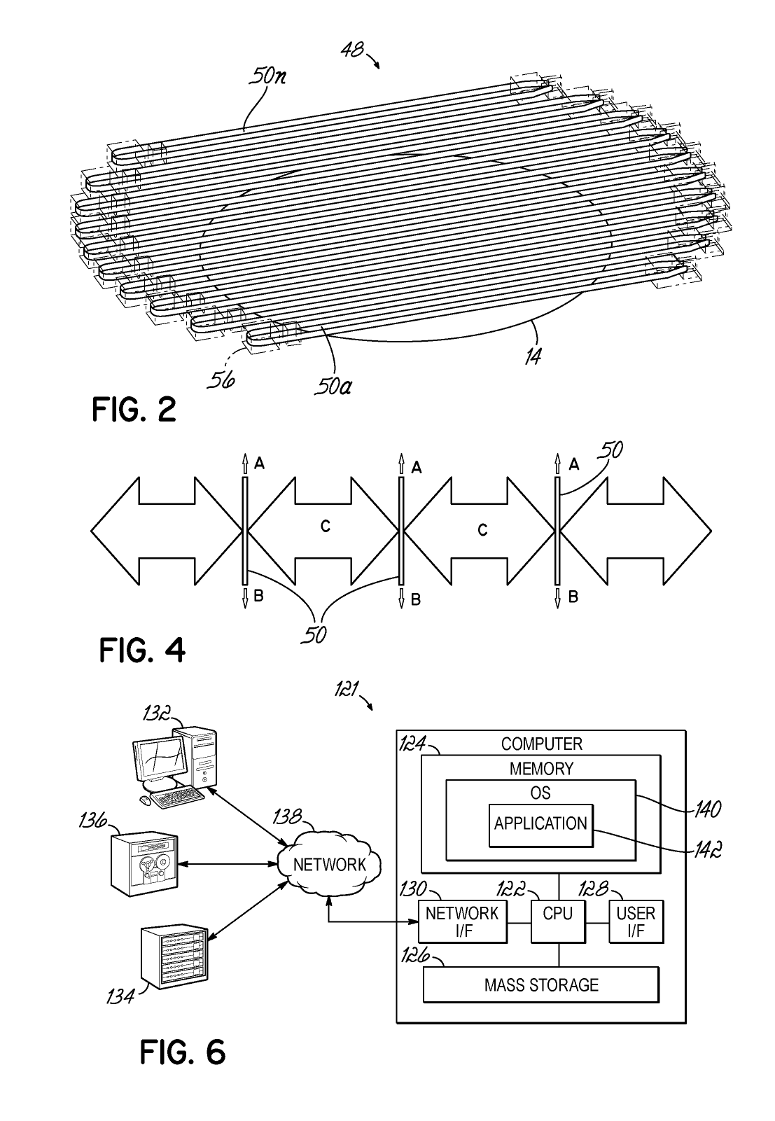

A heater, typically a filament assembly 48, is positioned within the processing space 12 between the gas distribution plate 46 and the substrate support 16 such that film forming materials flowing out of the gas distribution plate 46 may be thermally decomposed into radicals or fragments, and thus rendered reactive in a manner consistent with FACVD film deposition methods. The filament assembly 48, shown in greater detail in FIG. 2, may include a plurality of ribbon conductor pairs 50ₐ-50ₙ (“ribbon pairs 50”) that are powered in series by an external DC power source 52 (FIG. 1) via a DC circuitry 54. The DC power source 52 may be capable of voltage output of less than about 200 V and supplying power ranging from about 1 kW to about 5 kW such that the ribbon pairs 50 are capable of generating temperatures ranging from below 100° C. to about 1000° C. but are not limited to a given range. Ribbon pairs 50 may be alternatively arranged into a parallel connection in respect to the external DC source 52. Any electrically-conductive material may be used for the ribbon pairs 50, for example, nickel chromium. Ceramic posts 56 may be used to thermally and electrically insulate the ribbon pairs 50 from the walls of the reactor 10. Other configurations would be known and may include, for example, dynamic mounting devices to compensate for structural changes in the filament assembly 48 due to heating, such as those taught in U.S. patent application Ser. Nos. 12/044,574 and 12/559,398, the latter of which is incorporated herein by reference in its entirety.

Referring again to FIG. 1, a flow plate 58 is disposed between the filament assembly 48 and the gas distribution plate 46 of the gas delivery system 30. Generally, the flow plate 58 and the filament assembly 48 are configured to have a corresponding extent across a dimension of the reactor 10. While the illustrative embodiments are directed to corresponding extents across the diameter dimension of the reactor, other dimensions may also be used, such as a length or a height in the vertical processing of substrate or a width in the horizontal processing of the substrate. By arranging the extents across the diameter of the reactor, the flow plate 58 and the filament assembly 48 may be considered to be centered on a common axis and have substantially similar diameters. The flow plate 58 includes a plurality of openings 60 arranged to further distribute the film forming materials over the ribbon pairs 50. The flow plate 58 may be cooled, along with the walls of the reactor 10. Additional details and features of the flow plate 58 are discussed in greater detail below.

Referring still to FIG. 1, a controller 70 may be operably coupled to the reactor 10 to control one or more of the various systems (i.e., one or more of the temperature control elements 18, the substrate clamping system, the backside gas supply system, the vacuum pumping system 22, the gas delivery system 30, and the DC power source 52 of the filament assembly 48). Accordingly, the controller 70 may be a microprocessor having a memory and a digital I/O port that is capable of generating control voltages that are sufficient to communicate and activate inputs to one or more systems and to monitor outputs from the one or more systems. A program may be stored in the memory and may be operable to activate the inputs in accordance with a process recipe to achieve a particular process within the reactor 10. The controller 70 may be locally located relative to the reactor 10 or remotely located and operable via an intranet or the Internet. For example, the controller 70 may be coupled to an intranet at a customer site (i.e., a device maker) or coupled to an intranet at a vendor site (i.e., an equipment manufacturer). Furthermore, a computer (i.e., a server, etc.) may be used to access the controller 70 for exchanging inputs and outputs therewith via at least one of a direct connection, an intranet, or the Internet.

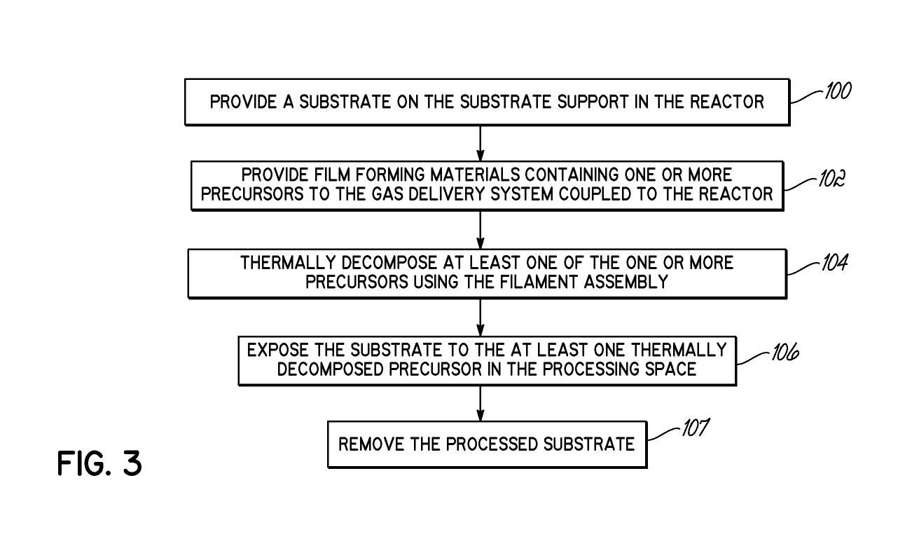

Turning now to FIG. 3, and with continued reference to the reactor 10 of FIG. 1, one illustrative method of operating the reactor 10 for depositing a thin film is shown. It would be understood that reactor designs may vary and that the particular illustrated embodiment of operating an FACVD system would not be limited to the particular reactor designs or the particular methods described herein.

In the illustrated method of operating the reactor 10, the method begins at Step 100 with providing one or more substrates 14 onto the upper surface of the substrate support 16 in the reactor 10. The one or more substrates 14 may be moved into and out of the reactor 10, without breaking the vacuum seal of the reactor 10, by a transfer system (not shown), as is well known in the art. Substrates 14 may be unprocessed substrates or previously patterned to include one or more vias. When a batch of substrates are processed in the reactor 10, the batch may include all unprocessed substrates, all previously patterned substrates, or a combination of processed and unprocessed substrates.

Once the one or more substrates 14 are so positioned, the method continues with providing film forming materials containing precursors 34, 36 to the gas delivery system 30 coupled to the reactor 10, at Step 102. As was described in greater detail above, the film forming materials may further include initiators 38, porogens, or other species that are desired to achieve a particular film formation on the substrate 14.

At about the time that the film forming materials are provided into the reactor 10, the DC power source 52 is energized for a film forming process time. It would be understood that the DC power source 52 may be activated prior to, simultaneously with, or just after, initiating the providing of the film forming materials to the gas delivery system 30. In that regard, the film forming materials flow through the gas delivery system 30, are mixed within the plenum 44 of the mixer manifold 42, flow out of the gas delivery system 30 through the orifices of the gas distribution plate 46, and are distributed by the flow plate 58 over the filament assembly 48, such that at least one of the precursors 34, 36 (FIG. 1) is thermally decomposed into radicals or fragments by the filament assembly 48, at Step 104.

At Step 106, the substrate 14 is exposed to the at least one thermally decomposed precursor and other film forming materials to facilitate the formation of the thin film on the surface of the substrate 14. During the exposing, the film forming materials, including the now reactive thermally decomposed precursor, adsorb onto the surface of the substrate 14. Accordingly, a number of reactions may occur on the surface of the substrate 14. For example, during a homopolymer deposition process, the various reactions may include:

TABLE 1

| | | Rate |
|---|---|---|
| Surface phase reactions | | constant |
| Physical adsorption | R₂(g) + S_{phys} → R₂(s) | k_{ads}^{R2} |
| (ads) of Initiator (R₂) | | |
| Recombination (rec) of initiator radicals (R^{•}) at the substrate surface | $\begin{matrix}{R}^{•} ( g ) + {R}^{•} ( s ) \\ {R}^{•} ( s ) + {R}^{•} ( s )\end{matrix} \} \to {R}_{2} ( s )$ | k_{rec}^{R}^{_{—}}^{ER} k_{rec}^{R}^{_{—}}^{LH} |
| Initiator desorption | R₂(s) → R₂(g) | k_{des}^{R2} |
| (des) | | |
| Monomer (M) | M(g) + s → M(s) | k_{ads}^{M} |
| adsorption | | |
| Monomer initiation on the surface | $\begin{matrix}{R}^{•} ( g ) + M ( s ) \\ {R}^{•} ( s ) + M ( s )\end{matrix} \} \to {RM}_{1}^{•} ( s )$ | kᵢ^{ER} kᵢ^{LH} |
| Polymer (Mᵢ^{•}) growth by propagation mechanism | $\begin{matrix}{M}_{1}^{•} ( s ) + M ( g ) \\ {M}_{1}^{•} ( s ) + M ( s )\end{matrix} \} \to {M}_{2}^{•} ( s )$ | kₚ^{ER} kₚ^{LH} |
| | $\begin{matrix}{M}_{n}^{•} ( s ) + M ( g ) \\ {M}_{n}^{•} ( s ) + M ( s )\end{matrix} \} \to {M}_{n + 1}^{•} ( s )$ | kₚ^{ER} kₚ^{LH} |
| Termination of the grown polymer | Mₙ^{•}(s) + Mₘ^{•}(s) → M_{n + m}(s) | kₜ^{a}^{_{—}}^{LH} |
| | Mₙ^{•}(s) + Mₘ^{•}(s) → Mₙ(s) + Mₘ(s) | kₜ^{b}^{_{—}}^{LH} |
| | $\begin{matrix}{R}^{•} ( g ) + {RM}_{n}^{•} ( s ) \\ {R}^{•} ( s ) + {RM}_{n}^{•} ( s )\end{matrix} \} \to {M}_{n} ( s ) + {R}_{2} ( s ) {↑}^{des}$ | kₜ^{c}^{_{—}}^{ER} kₜ^{c}^{_{—}}^{LH} |

wherein S_{phys} is indicative a site on the surface of the substrate 14 that is available for physical adsorbtion of a molecule, (g) is indicative of a molecule in the gas phase, (s) is indicative of a molecule adsorbed at the surface of the substrate 14, kᵢ is the rate constant associated with an initiation process, kₚ is the rate constant associated with the propagation mechanism of polymer growth, kₜ is the rate constant associated with a termination process, an ER superscript indicates a rate constant that is calculated in accordance with the Eley-Rideal mechanism of surface reactions, an LH superscript indicates a rate constant that is calculated in accordance with the Langmuir-Hinshelwood mechanism of surface reactions, the superscripts a, b, and c indicate differing channels of a growth termination process, and ↑^{des} indicates that the initiator may then undergo desorption.

Each reaction at the surface of the substrate 14 has an associated rate constant, k, which partially contributes to the overall rate of reaction of thin film deposition and formation. However, several additional factors may influence the rate of distribution and thermal decomposition of the precursor, which will also affect the rate of thin film deposition. These additional factors may include chamber pressure, diffusion rate of the precursor through the process space 12, fluidics associated with the particular structure of the gas distribution system 30, interior structural design of the reactor 10, positioning of the ducts 20 and vacuum pumping systems 22 relative to the process space 12, and the thermal properties of the various chemical species. Thus, it is possible that despite a uniform temperature distribution across the ribbon pairs 50, non-uniform thin film deposition onto the substrate 14 may result.

In that regard, it is well known to those of ordinary skill in the art that the rate of a reaction (here the thermal decomposition of the precursor) is dependent on temperature in accordance with the Arrhenius equation:

$$k = A {e}^{\frac{- {E}_{a}}{RT}}$$

where k is the rate of the reaction, A is the pre-exponential factor, Eₐ is the activation energy, R is the ideal gas constant, and T is the absolute temperature. Thermal decomposition of the precursors 34, 36 at the filament assembly 48 occurs through the transfer of heat energy to the precursors 34, 36 to varying degrees by the three heat transfer mechanisms: conduction, convection, and radiation. As is well known, conduction is accomplished through direct particle-to-particle transfer of energy; convection is the transfer of energy through a fluid or between a body and an adjacent fluid; and radiation is the transfer of energy from a body via electromagnetic waves.

At reduced temperature operations (below 500° C.), the heat transfer by radiation from the ribbon pairs 50 to the precursors 34, 36 is very low. At increased temperatures (above 500° C.), heat transfer by radiation is minimized in the vertical directions (indicated as “A” and “B” in FIG. 4) due to the thin metal construction of the ribbon pairs 50 (typically about 0.1 mm in thickness). Radiation loss by any one ribbon pair in the horizontal direction (indicated as “C”) is compensated by an adjacent ribbon pair. Heat transfer by convection is also typically minimized in FACVD processes because of the relatively low flow rates of the film forming materials (generally ranging from about 10 sccm to about 300 sccm). Thus, heat transfer in the filament assembly 48 is most likely due to conduction and will depend largely on the thermal properties of the carrier gas 32 and the geometry of the reactor 10.

Because heat transfer by conduction occurs through particle-to-particle interactions, larger distances are generally associated with a less effective heat transfer. Accordingly, cooled film forming materials emitted from the cooled flow plate 58 will generate less cooling effect on the ribbon pairs 50 when the distance separating the ribbon pairs 50 and the flow plate 58 is increased. By manipulating the distance separating the ribbon pairs 50 from the flow plate 58, cooling effects of the cooled film forming materials on the filament assembly 48 may be controlled, and localized heating zones may be created without the use of complex electrical circuit diagrams. As a result, a desired heat distribution profile of the filament assembly 48 may be accomplished by separating the filament assembly 48 from the flow plate 58 by different distances at different points measured from the common axis. The different points may be defined by first and second line segments extending from the common axis along the radius of either of the flow plate 58 or the filament assembly 48. These different distances may be accomplished by shaping the profile of the flow plate 58, using a non-planar filament assembly 48, or a combination thereof. To state another way, the filament assembly 48 and flow plate 58 are co-extensively opposed and physically separated or spaced apart from each other with varying degrees or distances of separation or spacing from their common axis to their peripheries or circumference, which varied spacing may increase or decrease, linearly or non-linearly, continuously or discontinuously along all or a portion of their extent or radii, and may include any combination of variations.

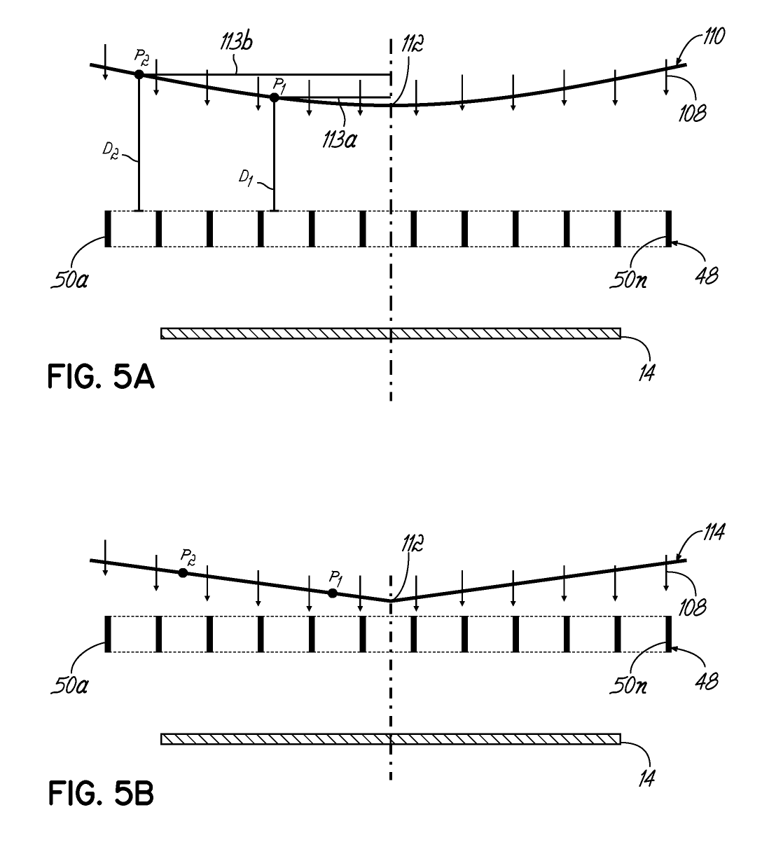

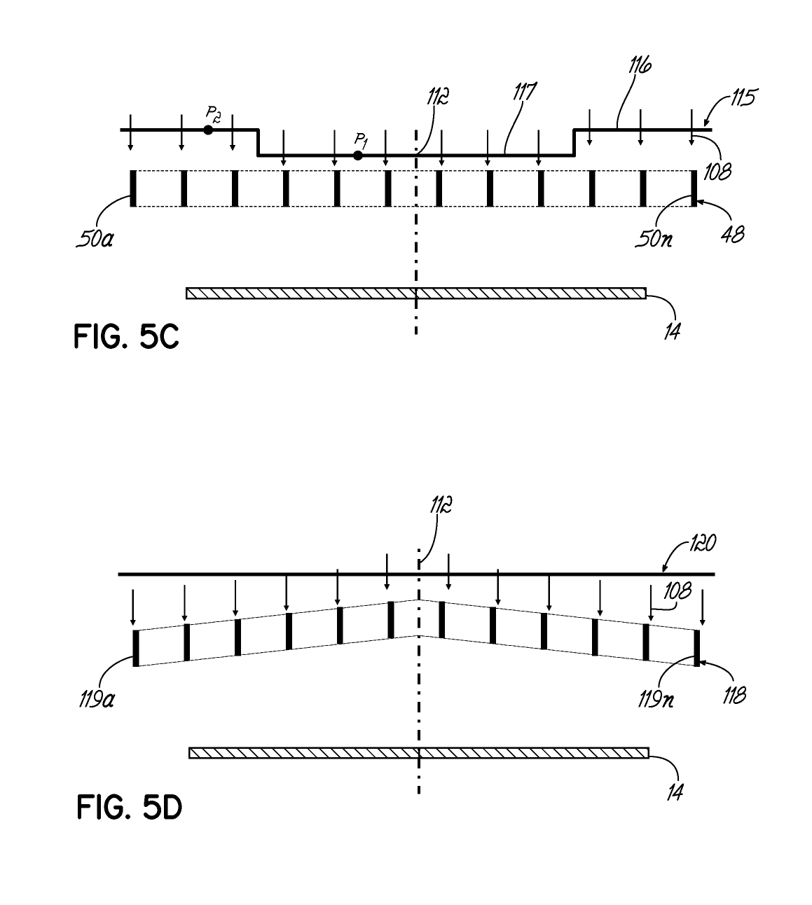

FIGS. 5A-5C schematically illustrate three exemplary profiles for flow plates that are operable to affect the heat distribution profile of the filament assembly 48. While the flow plate profiles are shown in cross-section, it would be readily appreciated that each profile is, in reality, a three-dimensional shape. Further, it should be noted that in each of these exemplary profiles, the plurality of openings 60 (FIG. 1) are shown (arrows 108) to be in direct, one-to-one alignment with each of the ribbon pairs 50. While this is a preferred arrangement to direct the film forming materials directly onto the ribbon pairs 50 for the most efficient heat transfer, this is not necessary and should not be considered to be limiting. In FIG. 5A, the flow plate 110 is shown to include a curved, convex cross-section about a central point 112 (or axis), thus the flow plate 110 would be a convex dome in three-dimensions. Two positions or points, P₁ and P₂, may be defined by line segments 113a, 113b extending from the common point 112. The flow plate 110 and the filament assembly 48 are separated by differing distances, D₁ and D₂, normal to the line segments 113a, 113b, respectively. While the particular embodiment shown in FIG. 5A is symmetric about the common point 112, i.e., P₁ and P₂ may define concentric circles having radii equal to line segments 113a, 113b, respectively, at which D₁ and D₂ are substantially constant at all points along the respective concentric circle, this is not necessary. Indeed, some geometries of the reactor 10 (FIG. 1) require an asymmetric flow plate design solution (i.e., lack of an axial symmetry) to offset the non-uniform deposition across the diameter of the substrate 14. Or, stated another way, the flow plate 110 has been shaped such that it is separated from the filament assembly 48 by differing distancing at a position P₁ as compared to a position P₂.

FIG. 5B shows a flow plate 114 having an incline from the central point 112, and thus is conical in three-dimensions. FIG. 5C shows a flow plate 115 having an outer step such that in three-dimensional space there is an inner ring 117 having one radius and an outer ring 116 encircling the inner ring 117 and having a second radius. While these particular illustrative embodiments all include larger distances between the filament assembly 48 and the particular flow plate at the periphery of the reactor 10, this is not necessary. Instead, it is envisioned that an inverse correlation may also be possible where the periphery of a flow plate is constructed to be closer to the filament assembly 48 than at the central point 112, such as in a concave dome. In addition, combinations of these profiles may also be possible, for example, a linear incline outwardly from the central point 112 for an inner portion of the extent, forming an inner conical portion, and a non-linear increase from the inner portion to the periphery, forming an outer convex dome portion (not shown).

FIG. 5D illustrates one exemplary embodiment of a non-planar heater assembly 118 suitable for creating the different distances between the non-planar heater assembly 118 and the planar flow plate 120 at different points along the radii. Specifically, the ribbon pairs 119ₐ-119ₙ are spaced increasingly further from the planar flow plate 120, from the central point 112 to the periphery, for example, in a continuous linear manner as shown.

While the illustrative embodiments of FIGS. 5A-5D exhibit a non-planar flow plate with a planar heater assembly or a non-planar heater assembly with a planar flow plate, it is envisioned that a non-planar flow plate and a non-planar heater assembly may be used together. For example, when a flexible substrate is processed by running roller-to-roller, then the heater assembly and flow plate may be non-planar, curved, and concave to better conform to the shape of the substrate over the roller-style substrate holder. As a result, one manner of creating different distances along the extent of the non-planar flow plate and heater assembly would be to include different radii of curvature for each of the flow plate and heater assembly. In this way, the distance between the non-planar flow plate and the non-planar heater assembly at their respective apices may be less than a distance between the non-planar flow plate and the non-planar heater assembly at their peripheries.

To effectuate the desired thermal decomposition profile of the precursor and to obtain a more uniform thin film formation on the substrate 14, the computational fluid dynamics and chemical engineering analysis of the reactor 10 may be modeled. FIG. 6 illustrates a hardware and software environment for a computing system 121 that may include an integrated circuit device (hereinafter “ICD”) consistent with embodiments of the invention and that may be used in modeling. The computing system 121, for purposes of this invention, may represent any type of computer, computer system, computing system, server, disk array, or programmable device such as multi-user computers, single-user computers, handheld devices, networked devices, etc. The computing system 121 may be implemented using one or more networked computers, e.g., in a cluster or other distributed computing system. The computing system 121 will be referred to as “computer” for brevity sake, although it should be appreciated that the term “computing system” may also include other suitable programmable electronic devices consistent with embodiments of the invention.

The computer 121 typically includes at least one processing unit 122 (illustrated as “CPU”) coupled to a memory 124 along with several different types of peripheral devices, e.g., a mass storage device 126, a user interface 128 (including, for example, user input devices and a display), and a network interface 130. The memory 124 may include dynamic random access memory (DRAM), static random access memory (SRAM), non-volatile random access memory (NVRAM), persistent memory, flash memory, at least one hard disk drive, and/or another digital storage medium. The mass storage device 126 is typically at least one hard disk drive and may be located externally to the computer 121, such as in a separate enclosure or in one or more networked computers 132, one or more networked storage devices 134 (including, for example, a tape drive), and/or one or more other networked devices 136 (including, for example, a server). The computer 121 may communicate with the networked computer 132, networked storage device 134, and/or networked device 136 through a network 138. As illustrated in FIG. 1, the computer 121 includes one processing unit 122, which, in various embodiments, may be a single-thread, multithreaded, multi-core, and/or multi-element processing unit as is well known in the art. In alternative embodiments, the computer 121 may include a plurality of processing units 122 that may include single-thread processing units, multithreaded processing units, multi-core processing units, multi-element processing units, and/or combinations thereof as is well known in the art. Similarly, memory 124 may include one or more levels of data, instruction, and/or combination caches, with caches serving an individual processing unit or multiple processing units as is well known in the art. In some embodiments, the computer 121 may also be configured as a member of a distributed computing environment and communicate with other members of that distributed computing environment through the network 138.

The memory 124 of the computer 121 may include an operating system 140 to control the primary operation of the computer 121 in a manner that is well known in the art. In a specific embodiment, the operating system 140 may be a Unix-like operating system, such as Linux. The memory 124 may also include at least one application 142, or other software program, configured to execute in combination with the operating system 140 and perform a task. It will be appreciated by one having ordinary skill in the art that other operating systems may be used, such as Windows, MacOS, or Unix-based operating systems, for example, Red Hat, Debian, Debian GNU/Linux, etc.

In general, the routines executed to implement the embodiments of the invention, whether implemented as part of an operating system or a specific application, component, algorithm, program, object, module or sequence of instructions, or even a subset thereof, will be referred to herein as “computer program code” or simply “program code.” Program code typically comprises one or more instructions that are resident at various times in memory and storage devices in a computer, and that, when read and executed by at least one processor in a computer, cause that computer to perform the steps necessary to execute steps or elements embodying the various aspects of the invention. Moreover, while the invention has been, and hereinafter will be, described in the context of fully functioning computers and computer systems, those skilled in the art will appreciate that the various embodiments of the invention are capable of being distributed as a program product in a variety of forms, and that the invention applies regardless of the particular type of computer readable media used to actually carry out the invention. Examples of computer readable media include, but are not limited to, recordable type media such as volatile and non-volatile memory devices, floppy and other removable disks, hard disk drives, tape drives, optical disks (e.g., CD-ROM's, DVD's, HD-DVD's, Blu-Ray Discs), among others, and transmission-type media such as digital and analog communications links.

In addition, various program code described hereinafter may be identified based upon the application or software component within which it is implemented in specific embodiments of the invention. However, it should be appreciated that any particular program nomenclature that follows is merely for convenience; and thus, the invention should not be limited to use solely in any specific application identified and/or implied by such nomenclature. Furthermore, given the typically endless number of manners in which computer programs may be organized into routines, procedures, methods, modules, objects, and the like, as well as the various manners in which program functionality may be allocated among various software layers that are resident within a typical computer (e.g., operating systems, libraries, Application Programming Interfaces [APIs], applications, applets, etc.), it should be appreciated that the invention is not limited to the specific organization and allocation of program functionality described herein.

Those skilled in the art will recognize that the environment illustrated in FIG. 6 is not intended to limit the present invention. Indeed, those skilled in the art will recognize that other alternative hardware and/or software environments may be used without departing from the scope of the invention.

The simulation according to an embodiment of the present invention for modeling of the heat distribution of the filament assembly 48 and the resultant affect on the film forming materials, and the computer method for such modeling, will now be described. The program code to simulate the reactor 10 may be executed as part of, or executed on behalf of, a software suite, application, command, or request. In some embodiments, the program code may be incorporated with, or executed on behalf of, device simulation software. In a specific embodiment, the program code may be incorporated with, or executed on behalf of, a version of COMSOL application/software suite as distributed by The COMSOL Group of Burlington, Mass. In alternative embodiments, the program code may be incorporated with, or executed on behalf of, mathematical software, such as a version of Fluent by ANSYS Corp or Mathematica by Wolfram Research, Inc.

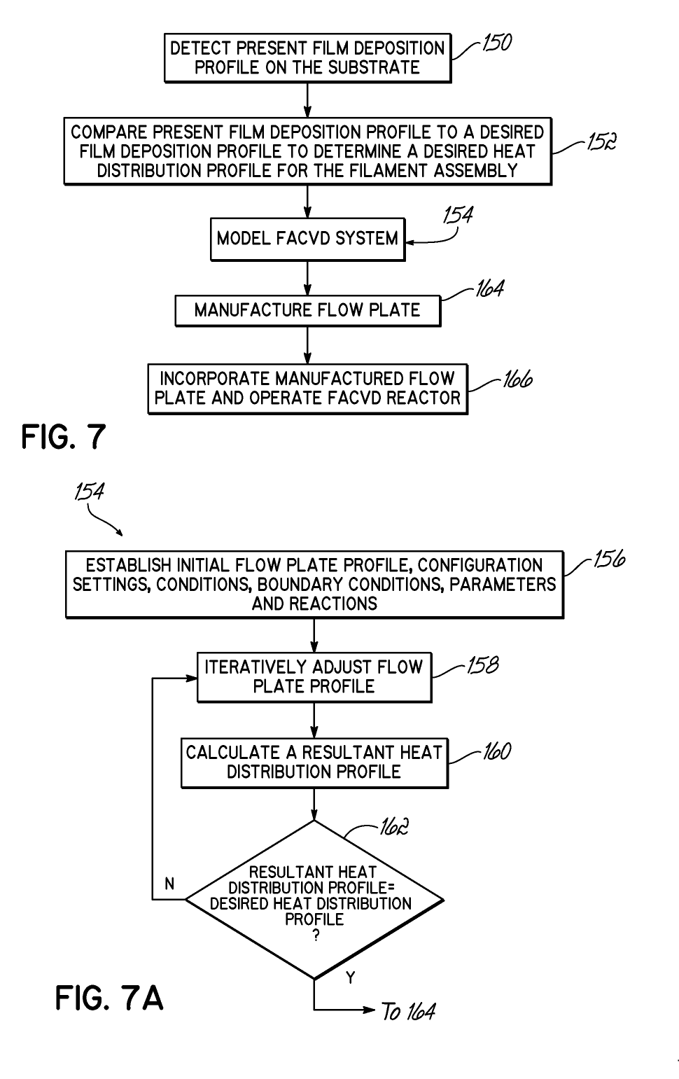

With reference now to FIGS. 7 and 7A as well as the FACVD system 11 of FIG. 1, one exemplary method of determining a desired flow plate profile is shown. In Step 150, a present film deposition profile on the substrate 14 is detected. This may be accomplished by imaging, the use of sensors, or other known methods of analyzing material deposition on a substrate 14. In Step 152, a comparison between the present film deposition profile to a desired film deposition profile is made. While the desired film deposition profile is typically uniform across the diameter of the substrate 14, this is not necessary. Typically, areas requiring additional thin film will require additional thermal decomposed film forming materials (i.e., reactive species). To increase the amount of thermally decomposed film forming material, the local temperature of the filament assembly 48 should be increased, which generally correlates to a larger distance separating the filament assembly 48 from the flow plate 58.

In Step 154, modeling of the FACVD system 11 is initiated. Therein, and with reference to FIG. 7A, Step 156 includes establishing an initial flow plate profile. The initial flow plate profile may be planar or may include an “educated guess” as to a suitable flow plate profile, as would be understood by one of ordinary skill in the art. Additionally, the configuration, initial operational conditions, boundary conditions, parameters, and chemical reactions associated with the thin film deposition process may also be established. The parameters of the thin film deposition process may include, for example, mathematical expressions that describe the fluid dynamics of the film forming materials from the gas delivery system 30, through the flow plate 58, and out of the reactor 10, and mathematical expressions related to the heat transfer mechanisms for the particular structure of the filament assembly 48. The chemical reaction may include the various surface reactions, such as those provided in detail in Table 1 above. In some embodiments, the flow plate profile may be modeled in two-dimensions (as explained above in FIGS. 5A-5C) in order to simply the model and reduce computational resources required in the modeling. Further simplifications of the model may be achieved by limiting the flow plate profile to those designs having an axial symmetry.

With the FACVD system 11 and initial conditions established, Step 158 includes an iterative adjustment of the flow plate profile. After a number of iterative adjustments, a resultant heat distribution profile is calculated in Step 160. In Step 162, a determination is made as to whether the resultant heat distribution profile is equal to the desired heat distribution profile. One of ordinary skill in the art would readily appreciate that the determination could be extended to accept resultant heat distribution profiles that are within a specified standard deviation of the desired heat distribution profile. If the resultant heat distribution profile is not satisfactorily similar to the desired heat distribution profile, then the process returns to Step 158 where further iterative adjustments to the flow plate profile are made.

If the resultant heat distribution profile is satisfactorily similar to the desired heat distribution profile, then the process may continue to Step 164 where, with reference to FIG. 7, manufacturing of a flow plate is accomplished in accordance with the specifications of the flow plate profile used in calculating the resultant heat distribution profile. In Step 166, the manufactured flow plate is incorporated within the FACVD system 11 and operation of the FACVD process may resume.

It would be readily appreciated that while the process may be complete after Step 166, it is possible that the process may be repeated at a later time and beginning again with Step 150 or at any other intermediary step, such as Step 156.

### Example 1

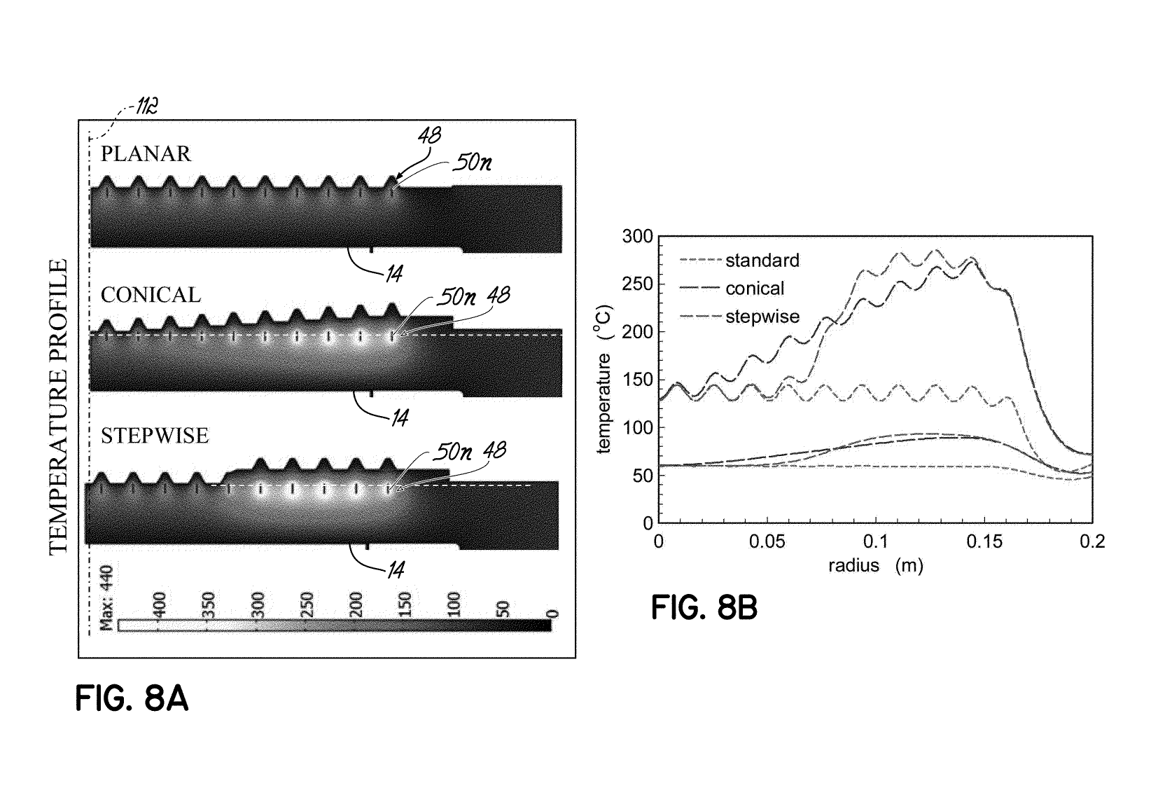

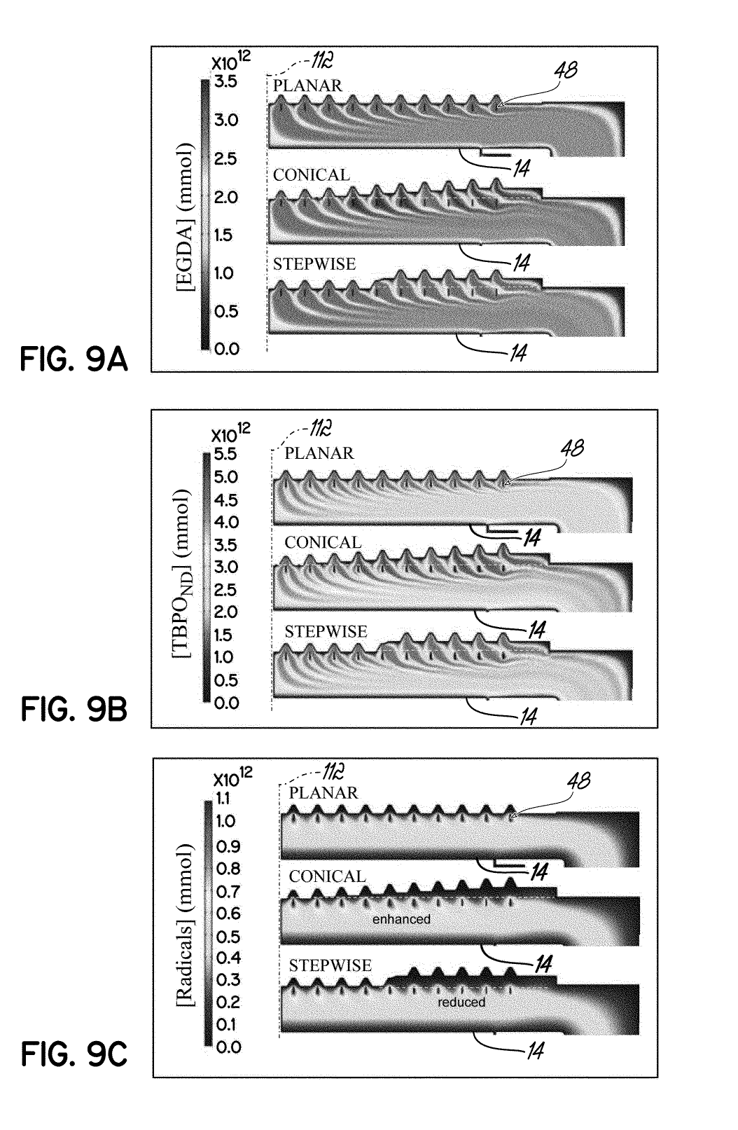

FIGS. 8A-9C illustrate the results of modeling the FACVD system 11 having the conical and stepwise shaped flow plates (114 and 115 of FIGS. 5B and 5C) relative to a planar flow plate. The specific modeled chemical reaction includes the use of ethylene glycol di-acrylate (EGDA) with a tert-butyl peroxide (TBPO) initiator. The reactor was a conventional FACVD system, such as the one shown in FIG. 1, operated at an internal pressure of 2 Torr. The flow rate of EGDA was 6 sccm and the flow rate of TBPO was 10 sccm. An Ar carrier gas was supplied at a flow rate of 150 sccm.

FIG. 8A illustrates the temperature profile along the radius of the ribbon pairs 50. In the planar flow plate configuration, the temperature profile at each ribbon 50 of the heater filament 48 is substantially uniform. In the conical flow plate configuration, the temperature profile demonstrates a gradual increase in temperature toward the periphery of the heater filament 48. In the stepwise configuration, the temperature profile demonstrates an abrupt increase in temperature at those ribbons 50n directly below the outer ring 116. The temperature profiles are graphically illustrated in FIG. 8B and where measurements were taken at about 5 mm below the heater filament 48 edge and about 5 mm above the surface of the substrate 14.

FIGS. 9A-9C illustrate the chemical species distributions that result from the above-described temperature profiles. In FIG. 9A, the concentration of the thermally decomposed precursor, EGDA, is shown to be significantly greater at the periphery of the filament assembly 48 for the conical and stepwise flow plate profiles as compared to similar locations on the planar flow plate profile. FIG. 9B illustrates the concentration of nondecomposed initiator, TBPO_{ND}, along the filament assembly 48 for the various flow plate profiles. As shown, the concentration of TBPO_{ND} is significantly greater at the periphery of the conical and stepwise flow plate profiles as compared to the planar flow plate profile. FIG. 9C illustrates the concentration of the radicals along the filament assembly 48 that result from the decomposition of the EGDA. The concentration of radicals is enhanced at a mid-point along the radius of the conical flow plate profile as compared to similar points on the planar flow plate profile. Radical concentration was reduced below the outer ring of the stepwise flow plate profile as compared with similar points on the planar flow plate.

While the present invention has been illustrated by a description of various embodiments, and while these embodiments have been described in some detail, they are not intended to restrict or in any way limit the scope of the appended claims to such detail. Additional advantages and modifications will readily appear to those skilled in the art. The various features of the invention may be used alone or in any combination depending on the needs and preferences of the user. This has been a description of the present invention, along with methods of practicing the present invention as currently known. However, the invention itself should only be defined by the appended claims.

What is claimed is:

1. A filament assisted chemical vapor deposition (FACVD) processing system comprising:
a reactor enclosing a processing space;
a substrate support positioned within the reactor on a first side of the processing space;
a gas distribution assembly positioned within the reactor on a second side of the processing space opposite the first side, the gas distribution assembly being operable to supply at least one reactive gas to the processing space;
a heater filament assembly positioned between the gas distribution assembly and the substrate support such that a flow of the at least one reactive gas supplied to the processing space flows therethrough, the heater filament assembly being configured to thermally decompose the at least one reactive gas when flowing therethrough; and
a flow plate disposed between the gas distribution assembly and the heater filament assembly, the flow plate being configured to direct the flow of the at least one reactive gas onto the heater filament assembly, wherein the flow plate and the heater filament assembly have a corresponding extent across a dimension of the reactor and are separated by different distances across the extent thereof.

2. The FACVD processing system of claim 1, wherein the dimension of the reactor is a diameter.

3. The FACVD processing system of claim 1, wherein the flow plate has an axial symmetry about a central axis.

4. The FACVD processing system of claim 1, wherein the flow plate is non-planar.

5. The FACVD processing system of claim 4, wherein the non-planar flow plate has a conical shape relative to the heater filament assembly.

6. The FACVD processing system of claim 4, wherein the non-planar flow plate has a concaved dome shape relative to the heater filament assembly.

7. The FACVD processing system of claim 4, wherein the non-planar flow plate has a convexed dome shape relative to the heater filament assembly.

8. The FACVD processing system of claim 4, wherein the non-planar flow plate includes at least one step.

9. The FACVD processing system of claim 8, wherein the at least one step creates an inner ring and an outer ring.

10. The FACVD processing system of claim 9, wherein the distance between the heater filament assembly and the inner ring is shorter than the distance between the heater filament assembly and the outer ring.

11. The FACVD processing system of claim 9, wherein the distance between the heater filament assembly and the inner ring is greater than the distance between the heater filament assembly and the outer ring.

12. The FACVD processing system of claim 1, wherein the heater filament assembly includes a plurality of ribbon pairs for resistively heating the at least one reactive gas.

13. The FACVD processing system of claim 1, wherein the heater filament assembly is non-planar.

14. The FACVD processing system of claim 1, wherein the flow plate and the heater filament assembly are centered on and symmetric relative to a common axis, the flow plate and heater filament assembly are separated by a first distance at a first point and by a second distance at a second point, and the first and second points are defined by first and second line segments extending from the common axis.

15. The FACVD processing system of claim 14, wherein the first distance is smaller than the second distance and the first line segment is shorter than the second line segment.

16. The FACVD processing system of claim 14, wherein the first distance is greater than the second distance and the first line segment is shorter than the second line segment.

17. The FACVD processing system of claim 14, wherein a transition between the first and second points is continuous.

18. The FACVD processing system of claim 14, wherein a transition between the first and second points is curved.

19. The FACVD processing system of claim 14, wherein a transition between the first and second points is discontinuous.

20. A filament assisted chemical vapor deposition (FACVD) processing system comprising:
a reactor enclosing a processing space;
a substrate support positioned within the reactor on first side of the processing space;
a gas distribution assembly positioned within the reactor on a second side of the processing space opposite the first side and being operable to supply at least one reactive gas to the processing space;
a heater filament assembly positioned between the gas distribution assembly and the substrate support such that a flow of the at least one reactive gas supplied to the processing space flows therethrough, the heater filament assembly being configured to thermally decompose the at least one reactive gas when flowing therethrough; and
a non-planar flow plate disposed between the gas distribution assembly and the heater filament assembly, the non-planar flow plate and the heater filament assembly are centered at a common axis and are separated by a first distance at a first point and by a second distance at a second point, wherein the first and second points are defined by first and second line segments extending from the common axis between the non-planar flow plate and the heater filament assembly, whereby the non-planar flow plate is configured to direct a flow of the at least one reactive gas onto the heater filament assembly.

21. The FACVD processing system of claim 20, wherein the flow plate has an axial symmetry relative to the common axis.

22. The FACVD processing system of claim 20, wherein the non-planar flow plate has a conical shape relative to the heater filament assembly.

23. The FACVD processing system of claim 20, wherein the non-planar flow plate has a concaved dome shape relative to the heater filament assembly.

24. The FACVD processing system of claim 20, wherein the non-planar flow plate has a convexed dome shape relative to the heater filament assembly.

25. The FACVD processing system of claim 20, wherein a transition between the first and second points is discontinuous.

26. The FACVD processing system of claim 20, wherein the non-planar flow plate includes an inner ring on which lies the first point and an outer ring on which lies the second point, with a stepped transition from the inner ring to the outer ring.

27. The FACVD processing system of claim 26, wherein the distance between the heater filament assembly and the inner ring is shorter than the distance between the heater filament assembly and the outer ring.

28. The FACVD processing system of claim 26, wherein the distance between the heater filament assembly and the inner ring is greater than the distance between the heater filament assembly and the outer ring.

29. A method of designing a flow plate to achieve a uniform film formation profile on a substrate within a filament assisted chemical vapor deposition (FACVD) processing system comprising a reactor enclosing a processing space, a substrate support positioned within the reactor on first side of the processing space for supporting the substrate, a gas distribution assembly positioned within the reactor on a second side of the processing space opposite the first side, a heater filament assembly positioned within the processing space, and a flow plate disposed between the heater filament assembly and the gas distribution assembly, the method comprising:
detecting a present film deposition profile on the substrate in the FACVD processing system;
comparing the present film deposition profile to a desired film deposition profile;
determining a desired heat distribution profile for the heater filament assembly in response to the comparing; and
modeling the FACVD processing system to determine a flow plate design in response to the determining, wherein the flow plate design is effective to achieve the desired film deposition profile.

30. The method of claim 29, wherein the modeling further comprises:
iteratively adjusting an initial flow plate design;
calculating a resultant heat distribution profile for the heater filament assembly; and
comparing the resultant heat distribution profile to the desired heat distribution profile.

31. The method of claim 29 further comprising:
manufacturing a replacement flow plate having the flow plate design; and
depositing a thin film onto the substrate with the replacement flow plate installed into the FACVD processing system.

32. A method of operating a filament assisted chemical vapor deposition (FACVD) processing system to deposit a thin film onto a substrate, wherein the FACVD processing system includes a reactor enclosing a processing space, a substrate support positioned within the reactor on first side of the processing space for supporting the substrate, a gas distribution assembly positioned within the reactor on a second side of the processing space opposite the first side, a heater filament assembly positioned within the processing space, and a flow plate disposed between the heater filament assembly and the gas distribution assembly, the method comprising:
depositing an at least one reactive material as the thin film onto the substrate;
detecting a present film deposition profile of the thin film on the substrate;
determining a corrected flow plate profile by modeling the FACVD processing system to achieve a desired film deposition profile;
replacing the flow plate with a corrected flow plate constructed in accordance with the corrected flow plate profile; and
continuing the depositing of the at least one reactive material as the thin film on the substrate.

33. The method of operating the FACVD processing system of claim 32, wherein the modeling further comprises:
comparing the present film deposition profile to the desired film deposition profile;
determining a desired heat distribution profile for the heater filament assembly;
iteratively adjusting an initial flow plate profile;
calculating a resultant heat distribution profile for the heater filament assembly from the iteratively adjusted flow plate profile; and
comparing the resultant heat distribution profile to the desired heat distribution profile.

34. A filament assisted chemical vapor deposition (FACVD) processing method for depositing a film on a substrate, the method comprising:
placing the substrate on a substrate support in a reactor on a first side of a processing space;
introducing at least one reactive gas into the reactor through a gas distribution assembly on a second side of the processing space opposite said first side;
flowing the introduced at least one reactive gas into the processing space through a heater filament assembly disposed between the gas distribution assembly and the substrate support and thermally decomposing the at least one reactive gas with heat provided by the heater filament assembly; and
directing the flow of the at least one reactive gas toward the heater filament assembly through a flow plate disposed between the gas distribution assembly and the heater filament assembly, the flow plate being shaped in relation to the heater filament assembly to provide differing distances to the heater filament assembly at a first position on the flow plate as compared to a second position on the flow plate.

35. The method of claim 34 wherein the reactor, the substrate support, the gas distribution assembly, the heater filament assembly, and the flow plate are generally circular and share a common axis, wherein the distance between the flow plate and the heater filament assembly varies as a function of position from the common axis.

36. The method of claim 34 wherein the distance differs in a direction that improves a uniformity of the film deposited on the substrate as compared to a film uniformity that would be deposited if the distance did not vary.

37. The method of claim 36 wherein the distance has been determined by modeling.
